(19) United States
(12) Patent Application Publication
(10) Pub. No.: US 2009/0236710 A1
(43) Pub. Date: Sep. 24, 2009

(54) COL SEMICONDUCTOR PACKAGE

(75) Inventors: Wan-Jung HSIEH, Hsinchu (TW); Chin-Fa WANG, Hsinchu (TW); Chin-Ti CHEN, Hsinchu (TW)

Correspondence Address: Muncy, Geissler, Olds & Lowe, PLLC, P.O. BOX 1364, FAIRFAX, VA, 22038-1364, US

(73) Assignee: POWERTECH TECHNOLOGY INC.

(21) Appl. No.: 12/051,445

(22) Filed: Mar. 19, 2008

(51) Int. Cl. H01L 23/495

(52) U.S. Cl. 257/676; 257/690; 257/E23.039

(57) ABSTRACT

A Chip-On-Lead (COL) semiconductor package is revealed, primarily comprising a plurality of leadframe's leads each having a carrying bar, a finger and a connecting portion connecting the carrying bar to the finger. A chip has a back surface attached to the carrying bars and is electrically connected to the fingers by a plurality of bonding wires. Therein, at least one of the bonding wires overpasses one of the connecting portions without electrical relationship. An insulation tape is attached onto the connecting portions in a manner to be formed between the overpassing section of the bonding wire and the overpast connecting portion so that electrical short can be avoided during wire-bonding processes of the COL semiconductor package. Therefore, the carrying bars under the chip have more flexibility in the layout design of COL semiconductor packages to use die pad(s) with smaller dimensions or even eliminate die pad.

### FIELD OF THE INVENTION

The present invention relates to semiconductor devices, especially to Chip-On-Lead COL) semiconductor packages.

### BACKGROUND OF THE INVENTION

In the conventional semiconductor packages, leads of leadframe have been widely implemented as chip carriers and as electrical media which can be divided into two major packaging types, Lead-On-Chip (LOC) and Chip-On-Lead (COL) where “Lead-On-Chip” means the leads are attached to the active surface of a chip with integrated circuits so that the leads are located above the chip during wire-bonding and “Chip-On-Lead” means the back surface of a chip is attached onto certain portions of the leads so that so that the chip is located above the leads during wire-bonding. The chip is electrically connected to the leads of a leadframe by a plurality of bonding wires formed by wire bonding technology. Normally, the lengths of the bonding wires of COL packages are much longer than the ones of the LOC packages, therefore, the bonding wires in COL packages are vulnerable to wire sweep during molding processes. Furthermore, the leads of the leadframe for COL packages have the issues of insufficient supports. That is why a plurality of die pads with large dimensions are necessary to locate at two opposing sides of the leads to enhance the support to the chip, but leading to limited layouts of the leads of a leadframe under a chip.

As shown in FIG. 1 and FIG. 2, a conventional semiconductor package 100 comprises a plurality of leads 110 from a leadframe, a chip 120, a plurality of bonding wires 130, and an encapsulant 150. The leads 110 are inwardly extended from two opposing sides of the encapsulant 150 with asymmetric lengths where the longer leads 110 at one side are used for attaching the chip 120. Each longer lead 110 has a finger 112 and a external lead 113 where the external leads 114 are outwardly extended from the side of the encapsulant 150 for external connections. The chip 120 has an active surface 121 and a corresponding back surface 122 where a plurality of bonding pads 123 are disposed on the active surface 121. The back surface 122 of the chip 120 is attached to the longer lead 110 by a die-attaching tape 160. The bonding pads 123 are electrically connected to the fingers 112 by the bonding wires 130. The encapsulant 150 encapsulates the chip 120, the fingers 112, and the bonding wires 130 with the external leads 114 of the leads 110 exposed from the encapsulant 150. As shown in FIG. I and FIG. 2, since the longer leads 110 with the chip 120 attached are suspended and can not provide sufficient support, therefore, a plurality of die pads 170 are disposed at two sides of the longer leads 110 to increase the support to the chip 120 and to avoid shifting or tilting of the chip 120 in the following processes leading to limited layouts of the longer leads 110 under the chip 120. Furthermore, as shown in FIG. 2, the layout of the longer leads 110 has to be arranged in fine pitches according to the bonding pads 123 of the chip 120 to ensure the wire-bonding directions of the bonding wires 130 aligned to the extending direction of the leads 110. Therefore, the layouts of the leads 110 under the chip 120 for COL packages are very limited with the internal leads extended and aligned to the bonding pads 123 of the chip 120. When the positions of the bonding pads 123 of a chip 120 are changed, the wire-bonding directions of the bonding wires 130 form an angle with the extending directions of the leads 110 leading to electrical short caused by contacting to the adjacent fingers of the leads 110 by the bonding wires 130 during wire-bonding or molding processes.

### SUMMARY OF THE INVENTION

The main purpose of the present invention is to provide a COL semiconductor package to avoid electrical short caused by wire bonding and to facilitate tile layouts of the leads of COL package with smaller die pads or without die pad.

The second purpose of the present invention is to provide a COL semiconductor package to avoid contaminations of adhesive to the fingers of COL packages so that lower cost adhesive can be implemented to reduce the package cost.

According to the present invention, a COL semiconductor package primarily comprises a plurality of leadframe's leads, a chip, a plurality of bonding wires, an insulation tape, and an encapsulant. Each lead has a carrying bar, a finger, a portion connecting the carrying bar with the finger. The chip has an active surface and a back surface where a plurality of bonding pads are disposed on the active surface and the back surface is attached to the carrying bars of the leads. The bonding pads are electrically connected to the fingers by the bonding wires where at least one of the bonding wires overpasses one of the connecting portions without electrical relationship. The insulation tape is attached to the connecting portions. The encapsulant encapsulates the chip, the bonding wires, the insulation tape, the fingers of the leads, and the connecting portions.

### DESCRIPTION OF THE DRAWINGS

FIG. 1 shows a cross-sectional view of a conventional COL semiconductor package.

FIG. 2 shows a top view of a conventional COL semiconductor package before encapsulation.

FIG. 3 shows a cross-sectional view of a COL semiconductor package according to the first embodiment of the present invention.

FIG. 4 shows a top view of the semiconductor package before encapsulation according to the first embodiment of the present invention.

FIG. 5 shows a partial three-dimensional view of the semiconductor package before encapsulation according to the first embodiment of the present invention.

FIG. 6 shows a partial top view of an insulation tape on the leads of the semiconductor package before encapsulation according to the first embodiment of the present invention.

FIG. 7 shows a partial cross-sectional view of the insulation tape on the leads of the semiconductor package before encapsulation according to the first embodiment of the present invention.

FIG. 8 shows a cross-sectional view of another COL semiconductor package according to the second embodiment of the present invention.

FIG. 9 shows a top view of the leads of the semiconductor package according to the second embodiment of the present invention.

FIG. 10 shows a top view of the semiconductor package before encapsulation according to the second embodiment of the present invention.

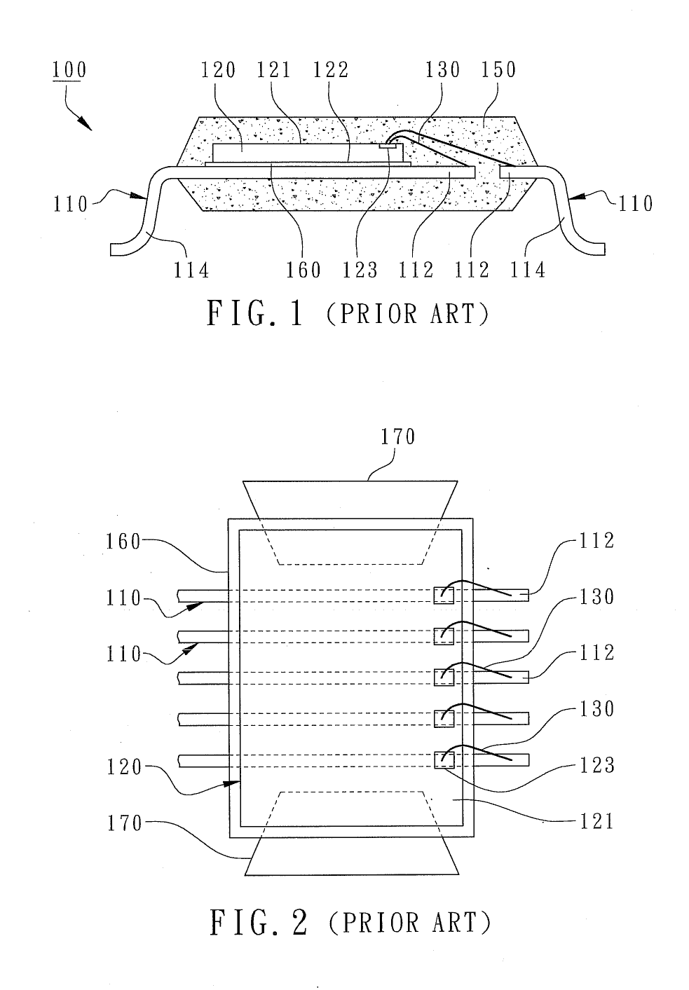

### DETAIL DESCRIPTION OF THE INVENTION

Please refer to the attached drawings, the present invention will be described by means of embodiments below.

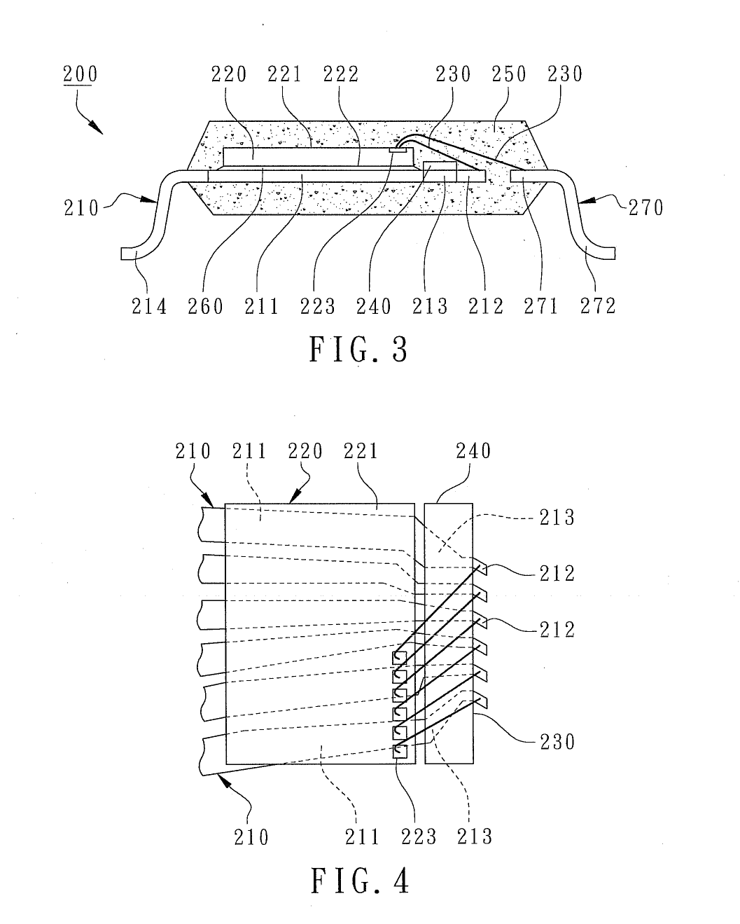

According to the first embodiment of the present invention, as shown in FIG. 3, a COL semiconductor package 200 primarily comprises a plurality of leads 210, a chip 220, a plurality of bonding wires 230, an insulation tape 240, and an encapsulant 250 where the leads 210 are made from a leadframe.

As shown in FIG. 4, each leads 210 has a carrying bar 211, a finger 212, and a portion 213 connecting the carrying bar 211 and the finger 212. The carrying bars 211 are the portions of the leads 210 inwardly extending from one side of the encapsulant 250 to underside of the chip 220 to support the chip 220. Moreover, in addition to the carrying bars 211, the internal leads of the leads 210 inside the encapsulant 250 further include the connecting portions 213 and the fingers 212 both extending outside the chip 220. As shown in FIG. 4, the widths and pitches of the carrying bars 211 are greater than the ones of the fingers 212 to provide larger and better support to the chip 220 and to enhance the stability and the packaging yield in the following packaging processes such as wire bonding and/or molding. In the present embodiment, each lead 210 further has an external lead 214 connecting the corresponding carrying bar 211 and externally extending from one side of the encapsulant 250 where the external leads 214 are bent as external terminals to SMT on an external printed circuit board, not shown in the figure. The external leads 214 can be bent into gull leads or other shapes Such as I leads or J leads. In this embodiment, as shown in FIG. 3 again, the semiconductor package 200 further comprises a plurality of second leads 270 shorter than the leads 210 and made from the same leadframe. Each second lead 270 has a finger 271 inside the encapsulant 250 and an external lead 272 extending outside the encapsulant 250.

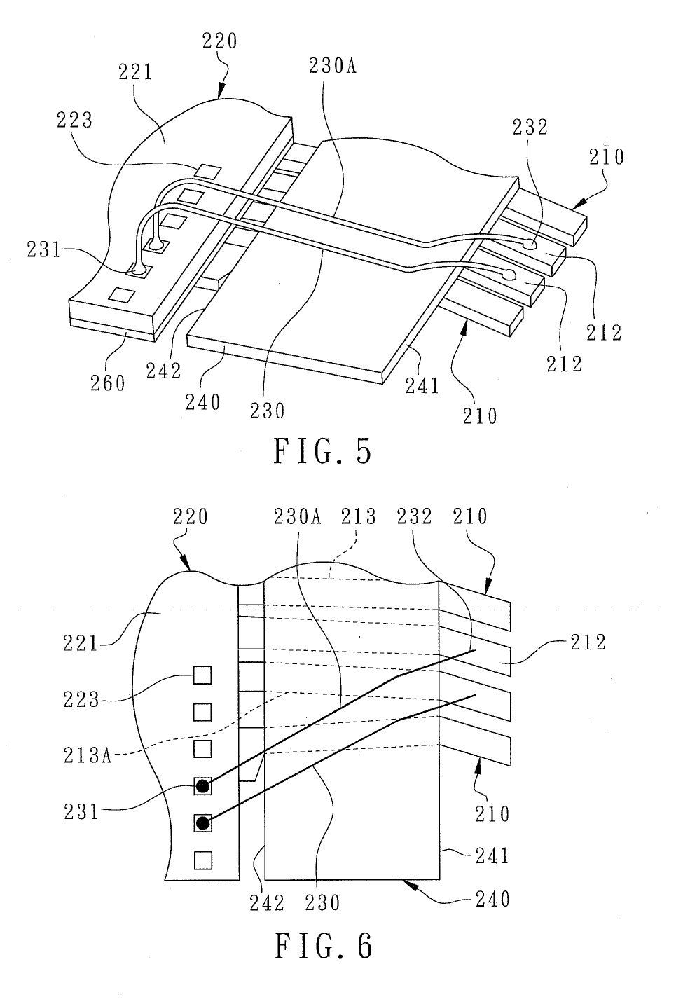

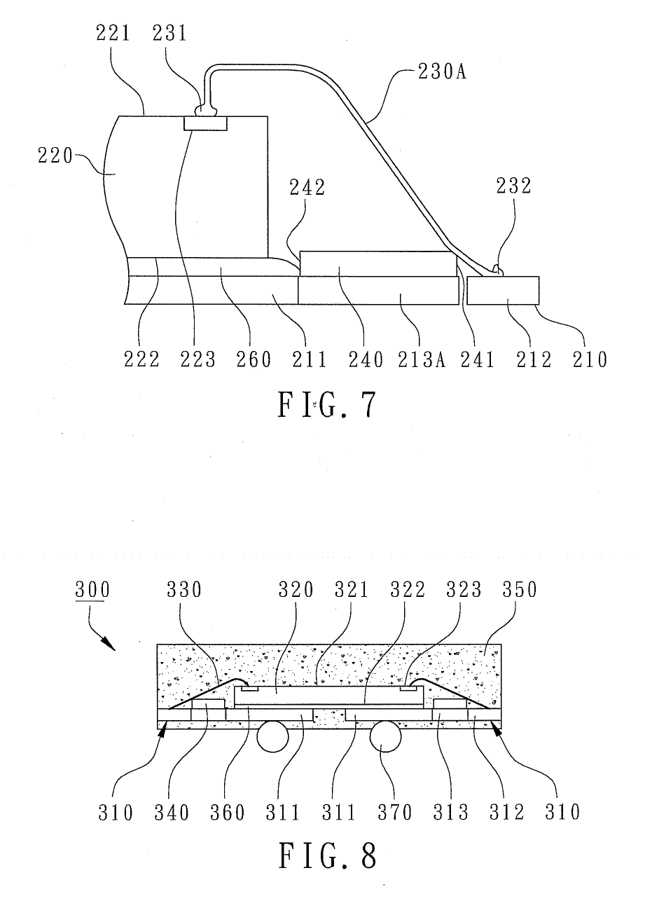

As shown in FIG. 3, the chip 220 has an active surface 221 and a back(surface 222 where a plurality of bonding pads 223 are disposed on the active surface 221. The back surface 222 of the chip 220 is attached to the carrying bars 211 of the leads 210. The bonding pads 223 are arranged adjacent one side of the chip 220 adjacent to the fingers 212 of the leads 210 to shorten the lengths of the bonding wires 230. To be more specific, the COL semiconductor package 200 further comprises an adhesive 260 mechanically connecting the back surface 222 of the chip 220 with the upper surface of the carrying bars 211. Therefore, the chip 220 can have a better Support with die pad(s) with smaller dimensions or without any die pad since the layout flexibility of the leads 210 under the chip 220 is increased leading to more variety of choices and designs of carrying bars 211. As shown in FIG. 3, the bonding wires 230 electrically connect the bonding pads 223 of the chip 230 to the fingers 212 or/and 271 of the leads 210 or/and 270. As shown in FIGS. 4, 5 and 6, the first ends 231 of the bonding wires 230 are bonded on the bonding pads 223 and the second ends 232 are bonded on the fingers 212. Therein, as shown in FIGS. 5 and 6 again, one bonding wire 230A of the bonding wires 230 overpasses at least one connecting portion 213A of the connecting portions 213 without electrical relationship. That is to say that one lead connected by the bonding wire 230A is electrically isolated from an adjacent lead having the overpast connecting portion 213A. As shown in FIGS. 5 and 7, the bonding wires 230 are formed by forward wire-bonding from the chip 220 to the leads 210, wherein the first ends 231 of the bonding wires 230 are the initiated ball bonds and the second ends 232 the terminated stitch bonds or wedge bonds. But in different embodiment without limitations, the bonding wires 230 can be formed by reversed wire bonding from the fingers 212 of the leads 210 to the bonding pads 223 of the chip 220.

As shown in FIG. 6 and FIG. 7, the insulation tape 240 is attached onto the connecting portions 213 including the overpast connecting portion 213A in a manner to be formed between the overpassing section of the bonding wire 213A and the overpast connecting portion 213A as shown in FIG. 7. This configuration can prevent electrical short between the overpassing bonding wire 230A and the overpast connecting portion 213A without electrical relationship vertically located under the bonding wire 230A due to wire sweeping or wire shifting during molding processes. In the present embodiment but not limited, the insulation tape 240 is a strip with single-side adhesion attaching to the connecting portions 213. Preferably, as shown in FIGS. 5 to 7, the insulation tape 240 has a first side 241 aligned to the fingers 212 and a second side 242 adjacent one side of the chip 220 in parallel so that the insulation tape 240 can be used as a dam for blocking the adhesive 260 to prevent the contaminations of adhesive 260 to the fingers 212. In this embodiment, the adhesive 260 is in contact with the second side 242 of the insulation tape 240 as shown in FIG. 7. Accordingly, the adhesive 260 can be chosen from the group consisting of B-stage resin and liquid epoxy to reduce packaging cost. To be more specific, the insulation tape 240 is thicker than the adhesive 260 to be more effective in controlling resin bleeding of the adhesive 260. As shown in FIG. 7, the insulation tape 240 is not thicker than the chip 220 so that the loop heights of the bonding wires 230 are not affected. As shown in FIG. 3, the encapsulant 250 encapsulates the chip 220, the bonding wires 230, the insulation tape 240, and the fingers 212 and the connecting portions 213 of the leads 210 to avoid external contaminations. In this embodiment, the encapsulant 250 further encapsulates the lower surfaces of the carrying bars 211. The encapsulant 250 can be formed by transfer molding. Therefore, the widths and the pitches of the carrying bars 211 of the leads 210 can be appropriately adjusted to increase the Support to the chip 220 and the connecting portions 213 can appropriately bend or turn according to different layouts of bonding pads 223 of the chip 220 so that the layout of the carrying bars 211 of the leads 210 can be appropriately designed to reduce the dimension of the die pads or even eliminate the die pad. Furthermore, the electrical short between the overpassing bonding wire 230A and the overpast connecting portions 213A without electrical relationship can be avoided by the deposition of the insulation tape 240. Moreover, liquid type or B-stage adhesive 260 can be implemented to reduce the packaging cost and to avoid contaminations of adhesive 260 to the fingers 212.

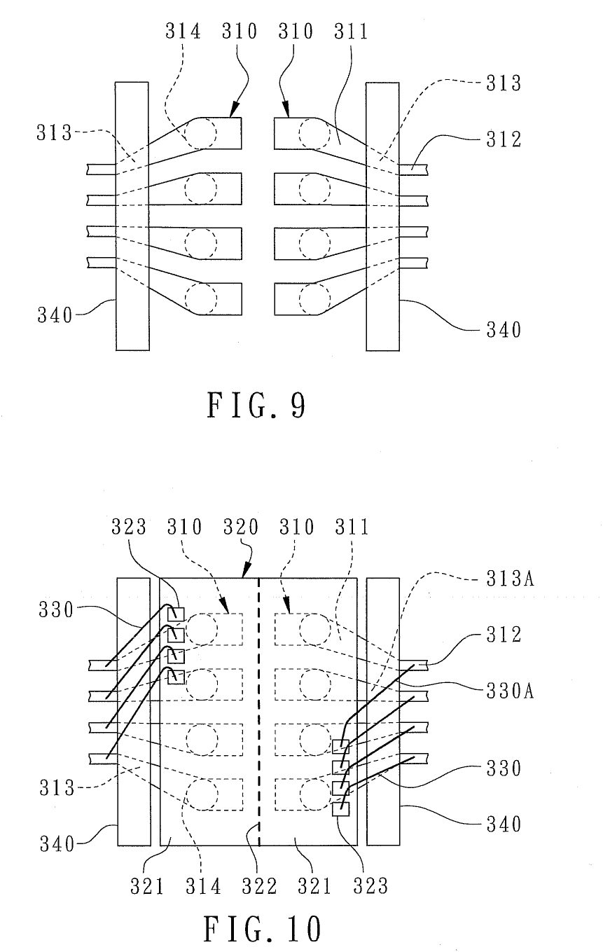

According to the second embodiment of the present invention, another COL semiconductor package 300 is revealed as shown in FIG. 8, primarily comprising a plurality of leadframe's leads 310, a chip 320, a plurality of bonding wires 330, at least an insulation tape 340, and an encapsulant 350. As shown in FIG. 9, each lead 310 has a carrying bar 311, a finger 312, and a connecting portion 313 connecting the carrying bar 311 and the finger 312. The external ends of the leads 310 are located at two opposing sides of the encapsulant 350 and the internal ends extend toward a central line of the back surface 322 of the chip 320 where the fingers 312 are far away from the internal ends of the leads 310. In this embodiment, the leads 310 further have a plurality of external pads 314, as shown in FIG. 9, formed on the unloading surfaces of the carrying bars 311. The unloading surface means a surface of the carrying bar 311 opposing to the upper surface attached by the chip 320. As shown in FIG. 8, the chip 320 has an active surface 321 and a back surface 322 where a plurality of bonding pads 323 are disposed on the active surface 321. The back surface 322 is attached to the upper surfaces of the carrying bars 322 of the leads 310 by an adhesive 360. As shown in FIG. 10, in the present embodiment, the bonding pads 323 are arranged on two opposing sides of the chip 320. Preferably, the chip 320 includes a plurality of IC units 321 having a wafer scribe line 322 therebetween, as shown in FIG. 10, where the wafer scribe line 322 integrally connecting the IC units 321. To be more specific, the adhesive 360 is a die attach material (DAM) where the adhesive 360 is pre-formed on the back surface 322 of the chip 320 by partially curing at wafer stage so that the covering area of the adhesive 360 be almost the same as the back surface 322. The adhesive 360 becomes adhesive during heating to attach onto the upper surfaces of the carrying bars 322. Under appropriate bonding pressure and heating temperatures, the adhesive 360 can mechanically connect the carrying bars 311 to firmly hold the chip 320 on the carrying bars 311. Accordingly, the fingers 312 can be closer to the chip 320 without the issue of contamination by the adhesive 360. The width of the insulation tape 340 can be reduced to form as a strip, as shown in FIG. 9.

As shown in FIG. 10, the bonding pads 323 are electrically connected to the fingers 312 by the bonding wires 330 wherein at least one bonding wire 330A of the bonding wires 330 overpasses at least one connecting portion 31 3A of the connecting portions 313 without electrical relationship. The insulation tape 340 is attached onto the connecting portions 313 to avoid electrical short between the overpassing bonding wire 330A and the overpast connecting portion 313A without electrical relationship. As shown in FIG. 8, the encapsulant 350 encapsulates the chip 320, the bonding wires 330, the insulation tape 340, and the fingers 312 and the connecting portions 313 of the leads 310. As shown in FIG. 9, the COL semiconductor package 300 further comprises a plurality of external terminals 370 disposed on the external pads 314 (as shown in FIG. 8) of the carrying bars 3 11. Therefore, according to the present invention, the layout of the carrying bars 3 11 of the COL semiconductor package 300 is flexible and the leads 310 can electrically connect to the chip 320 with different bonding pads layout without any electrical short by wire-bonding. The above description of embodiments of this invention is intended to be illustrative and not limiting. Other embodiments of this invention will be obvious to those skilled in the art in view of the above disclosure.

What is claimed is:

1. A semiconductor package primarily comprising:
a plurality of leadframe's leads, having a plurality of carrying bars, a plurality of fingers, and a plurality of connecting portions connecting the carrying bars with the fingers correspondingly;
a chip having an active surface, a back surface opposing to the active surface and a plurality of bonding pads disposed on the active surface, wherein the back surface is attached to the carrying bars;
a plurality of bonding wire connecting the bonding pads and the fingers, wherein at least one of the bonding wires overpasses an overpast connecting portion of the connecting portions without electrical relationship;
an insulation tape attached onto the connecting portions without extending to the fingers and attached to the connecting portions in a manner to be formed between an overpassing section of the bonding wire and the overpast connecting portion;
an encapsulant encapsulating the chip, the bonding wires, the insulation tape, the fingers and the connecting portions of the leads; and
an adhesive directly connecting the back surface of the chip with the carrying bars;
wherein the insulation tape has a first side aligned to the fingers and a second side adjacent one side of the chip in parallel without extending beneath the back surface.

2. (canceled)

3. (canceled)

4. The semiconductor package as claimed in claim 1, wherein the adhesive is in contact with the second side of the insulation tape.

5. The semiconductor package as claimed in claim 1, wherein the adhesive is chosen from the group consisting of B-stage resin and liquid epoxy.

6. (canceled)

7. The semiconductor package as claimed in claim 1, wherein the insulation tape has a thickness smaller than a thickness of the chip.

8. The semiconductor package as claimed in claim 1, wherein the leadframe's leads further have a plurality of external leads connecting the carrying bars correspondingly and externally extending from the encapsulant.

9. (canceled)

10. (canceled)

11. The semiconductor package as claimed in claim 1, wherein the insulation tape is a strip with single-side adhesion.
